(19) United States
(12) Patent Application Publication
(10) Pub. No.: US 2015/0228857 A1
(43) Pub. Date: Aug. 13, 2015

(54) NITRIDE SEMICONDUCTOR DEVICE

(71) Applicant: USHIO DENKI KABUSHIKI KAISHA, Tokyo (JP)

(72) Inventors: Masashi Tsukihara, Himeji-shi (JP); Kohei Miyoshi, Himeji-shi (JP); Koji Kawasaki, Kyoto-shi (JP)

(73) Assignee: USHIO DENKI KABUSHIKI KAISHA, Tokyo (JP)

(21) Appl. No.: 14/423,262

(22) PCT Filed: Aug. 29, 2013
(86) PCT No.: PCT/JP2013/073106

§ 371 Date: Feb. 23, 2015

(30) Foreign Application Priority Data
Aug. 31, 2012 (JP) 2012-191088

(51) Int. Cl. H01L 33/32; H01L 33/14

(52) U.S. Cl. CPC H01L 33/325; H01L 33/14

(57) ABSTRACT

Disclosed herein are a nitride semiconductor device that operates at lower operating voltage and that has higher luminous efficiency. The nitride semiconductor device according to embodiments of the present invention has an electron supply layer composed of N-type semiconductor. The electron supply layer has a composition of AlxGa1-xN (where 0.01<x≦1); a concentration of N-type impurity equal to or greater than 1×10¹⁹/cm³; and a thickness equal to or greater than 0.5 μm. Further, the N-type impurity is preferably silicon (Si).

### FIELD OF THE INVENTION

The present invention relates to a nitride semiconductor device that has an electron supply layer composed of an N-type semiconductor. More particularly, the present invention relates to a nitride semiconductor device that is suitable for the use in a light emitting diode (LED) and a laser diode (LD) and the like.

### DESCRIPTION OF THE RELATED ART

A nitride semiconductor device that is a nitride of a group III element including aluminum (Al), gallium (Ga) and indium (In) or the like is commonly used as a short (shorter) wavelength luminous element such as a short wavelength light emitting diode (LED) or a short wavelength laser diode (LD) or the like. This type of nitride semiconductor device is configured such that a luminous layer having a quantum well structure is interposed between an electron supply layer composed of a N-type semiconductor and a hole supply layer composed of a P-type semiconductor layer.

In such type of nitride semiconductor device, it is of paramount importance to lower the resistance of an element (or device) in order to achieve higher luminous efficiency (efficacy). In this regard, conventionally, in order to achieve lower resistance of the nitride semiconductor device, it has been proposed that an N-type semiconductor layer in a nitride semiconductor device is formed (composed) of a laminated body. In this laminated body, a high concentration layer in which an N-type impurity such as silicon (Si) is doped at high concentration and low concentration layer in which an N-type impurity is doped at lower concentration than the high concentration layer are respectively laminated. (See, e.g., Japanese Patent Application Laid-open Publication No. 2007-258529A: Patent Literature 1).

### LISTING OF REFERENCE

### Patent Literature

Patent Literature 1: Japanese Patent Application Laid-open Publication No. 2007-258529A

### SUMMARY OF THE INVENTION

### Problems to be Solved by the Invention

However, in the above mentioned nitride semiconductor device, in case that a gallium nitride (GaN), which is typically used for a blue LED, is employed as a material for configuring the N-type semiconductor layer, when the N-type impurity is doped in the N-type semiconductor layer at high concentration, roughness on a film (roughened film) occurs on a surface of the N-type semiconductor layer obtained. For this reason, it entails problems that the luminous efficiency of the obtained nitride semiconductor device is lowered, and that the operating voltage of the nitride semiconductor device unintentionally rises.

The present invention has been made in view of the above mentioned circumstances and its object is to provide a nitride semiconductor device that operates at a lower operating voltage and that is capable of obtaining higher luminous efficiency.

### Solution to the Problem

According to a first aspect of the present invention, there is provided a nitride semiconductor device, comprising: an electron supply layer composed of an N-type semiconductor. The electron supply layer has: a composition of AlₓGa₁₋ₓN (where 0.01<x≦1); a concentration of N-type impurity equal to or greater than 1×10¹⁹/cm³; and a thickness equal to or greater than 0.5 μm.

According to a second aspect of the present invention, in the nitride semiconductor device, the N-type impurity may be preferably silicon (Si).

### Advantageous Effect of the Invention

According to the above mentioned aspects of the nitride semiconductor device of the present invention, since the electron supply layer has a composition of AlₓGa₁₋ₓN (where 0.01<x≦1), even if the N-type impurity is doped at high concentration, an electron supply layer with even (flat) surface can be obtained. In addition, since the concentration of N-type impurity of the electron supply layer is equal to or greater than 1×10¹⁹/cm³, it can be achieved to lower the resistance of the electron supply layer. As a result, the nitride semiconductor device can be provided that operates at lower operating voltage, and that is capable of obtaining higher luminous efficiency.

### BRIEF DESCRIPTION OF THE DRAWINGS

FIG. 1 is a cross-sectional view showing an exemplary configuration of a nitride semiconductor device according to an embodiment of the present invention; and

FIG. 2 is a cross-sectional view showing another exemplary configuration of a nitride semiconductor device according to another embodiment of the present invention.

### DETAILED DESCRIPTION OF THE INVENTION

Hereinafter, embodiments of a nitride semiconductor device according to the present invention will be explained in detail with reference to the drawings attached hereto.

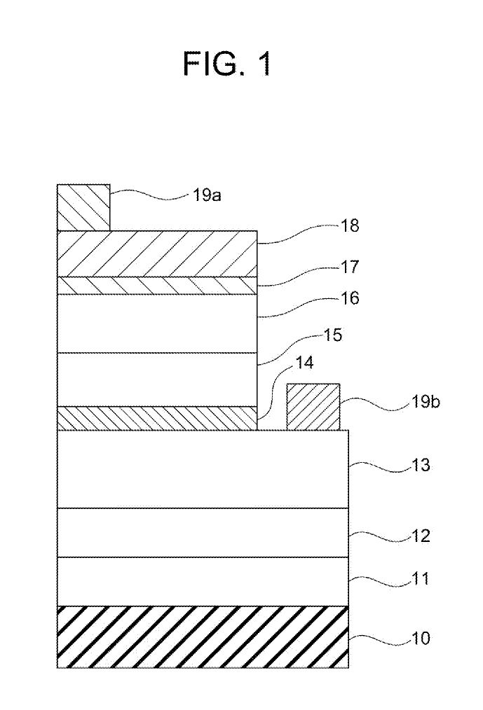

FIG. 1 is a cross-sectional view showing an exemplary configuration of a nitride semiconductor device according to an embodiment of the present invention. The nitride semiconductor device of the FIG. 1 has a lateral type structure composed as a LED, and includes a substrate 10 composed of, for example, sapphire. On the substrate 10, an electron supply layer 13 composed of an N-type nitride semiconductor is formed via (through) a low temperature buffer layer 11 and a base (ground) layer 12, both of which are composed of the nitride semiconductor, respectively. On the electron supply layer 13, a luminous layer 15 is formed via (through) a protective layer 14 composed of a P-type GaN of which size is smaller than the electron supply layer 13. On the luminous layer 15, a hole supply layer 16, which is composed of a P-type nitride semiconductor, is formed. On the surface of the hole supply layer, a P- electrode layer 18 composed of nickel/gold via (through) a contact layer 17 composed of N-type GaN. On the P- electrode layer 18, P- pad electrode 19a, which is composed of chromium/gold, is formed. On the other hand, N- pad electrode 19b, which is composed of chromium/gold, is formed on a region of the electron supply layer 13 on which the luminous layer 15 is not formed.

A thickness of the substrate 10 is, for example, 0.2 to 2 mm.

As a nitride semiconductor that constitutes the low temperature buffer layer 11 and the base layer 12, GaN single crystal (quartz) and AlGaN single crystal or the like in which an impurity is not doped can be used.

A thickness of the low temperature buffer layer 11 is, for example, 10 to 100 nm.

As such, a thickness of the base layer 12 is, for example, 0.5 to 5 μm.

The N-type nitride semiconductor which constitutes the electron supply layer 13 has a composition of AlₓGa₁₋ₓN (where 0.01<x≦1). In the nitride semiconductor which constitutes the electron supply layer 13, when a ratio of Al is too small, then it becomes difficult to form the electron supply layer 13 that has an even (flat) surface.

Furthermore, a concentration of N-type impurity in the N-type nitride semiconductor constituting the electron supply layer 13 is equal to or greater than 1×10¹⁹/cm³, and is preferably from 1×10¹⁹/cm³ to 1×10²⁰/cm³. When the concentration of N-type impurity is too small, then it becomes difficult to lower the resistance of the electron supply layer 13.

As exemplary N-type impurities in the N-type nitride semiconductor, for example, silicon (Si), germanium (Ge), sulfur (S), selenium (Se), tin (Sn) and tellurium (Te) and the like can be used. Nevertheless, among those elements, silicon (Si) can be preferably used.

Furthermore, the thickness of the electron supply layer 13 is equal to or greater than 0.5 μm, and is preferably 0.6 to 5 μm. When the thickness of the electron supply layer 13 is too small, then a spread of current may be insufficient. For this reason, when the current is injected into the electron supply layer 13, current concentration area is unintentionally created so that the device performance (characteristics) may be lowered.

The luminous layer 15 has a single quantum well structure or multiple quantum well (wells) structures that comprises a quantum well layer composed of, for example, GaInN or the like and a barrier layer composed of, for example, AlGaSiN or the like.

The thickness of the quantum well layer is, for example, 1 to 50 nm. Likewise, the thickness of the barrier layer is, for example, 5 to 100 nm.

Moreover, a periodic structure (cyclic structure) of the quantum well layer can be determined as appropriate by taking the thicknesses of the quantum well layer, the barrier layer and the whole luminous layer 15 or the like into consideration. Nevertheless, the periodic structure (cyclic structure) of the quantum well layer is commonly formed by repeating 1 to 50 cycles (layers).

The P-type nitride semiconductor which constitutes the hole supply layer 16 is formed with, for example, AlGaN.

Further, for the P-type impurity in the P-type semiconductor, magnesium (Mg), beryllium (Be), zinc (Zn) and carbon (C) and the like can be used.

Furthermore, the hole supply layer 16 may be formed with a laminated body by laminating a plurality of P-type AlGaN layers each of which a composition ratio of Al and Ga differs one another.

Moreover, the thickness of the hole supply layer 16 is, for example, 0.05 to 1 μm.

The above mentioned nitride semiconductor device can be fabricated by use of the metal organic chemical vapor deposition (MOCVD) method as follows.

### [Forming the Low Temperature Buffer Layer and the Base Layer]

First, the substrate 10 is disposed within a treatment (processing) furnace of the CVD equipment. Then, in-furnace temperature is elevated up to, for example, 1,150 degrees Celsius with flowing, for example, a hydrogen gas in the treatment furnace so as to clean the substrate 10.

Subsequently, an in-furnace pressure and an in-furnace temperature are set to predetermined values, respectively. Then, a source gas is supplied into the treatment furnace with flowing a nitrogen gas and a hydrogen has as a carrier gas therein. Thus, the low temperature buffer layer 11 is formed on the substrate 10 by the vapor phase epitaxial growth method.

Yet subsequently, an in-furnace pressure and an in-furnace temperature are set to predetermined values, respectively. Then, a source gas is supplied into the treatment furnace so that the base layer 12 is formed on a surface of the low temperature buffer layer 11.

In the above mentioned preparation, as the source gas, trimethyl gallium and trimethyl aluminum can be used as a group III element source, and ammonia can be used as a nitrogen source, respectively.

The low temperature buffer layer 11 is formed under a condition that the in-furnace pressure is, for example, 100 kPa and the in-furnace temperature is, for example, 480 degrees Celsius.

Likewise, the base layer 12 is formed under a condition that the in-furnace pressure is, for example, 100 kPa and the in-furnace temperature is, for example, 1,150 degrees Celsius.

### [Forming the Electron Supply Layer and the Protective Layer]

Subsequently, the in-furnace pressure and the in-furnace temperature are set to predetermined values, respectively. Then, a trimethyl gallium, trimethyl aluminum, ammonia and tetraethyl silane, all of which are as source gases, are supplied into the treatment furnace with flowing a nitrogen gas and a hydrogen gas, both of which are as carrier gases, into the treatment furnace. Thus, the electron supply layer 13 composed of the N-type nitride semiconductor is formed on a surface of the base layer 12 by the vapor phase epitaxial growth method. Subsequently, a source gas other than trimethyl aluminum is supplied into the treatment furnace so that the protective layer 14 is formed on a surface of the electron supply layer 13 by the vapor phase epitaxial grown method.

A ratio (flow ratio) of trimethyl gallium to trimethyl aluminum, both of which are used as metal element sources, can be set as appropriate according to the composition of the electron supply layer 13 to be formed.

The electron supply layer 13 is formed under a condition that the in-furnace pressure is, for example, 30 kPa and the in-furnace temperature is, for example, 1,150 degrees Celsius.

### [Forming the Luminous Layer]

Yet subsequently, the in-furnace pressure and the in-furnace temperature are set to predetermined values, respectively. Then, trimethyl gallium, tri methyl indium and ammonia, all of which are as source gases, are supplied into the treatment furnace, with flowing a nitrogen gas and a hydrogen gas, both of which are as carrier gases. After then, trimethyl gallium, trimethyl aluminum, tetraethyl silane and ammonia, all of which are as source gases, are also supplied into the treatment furnace. The above gas supplying operations are repeated. As a result, on a surface of the electron supply layer 13, the luminous layer 15 is formed that has a quantum well structure comprising the quantum well layer composed of GaInN and the barrier layer composed of N-type AlGaN in which silicon (Si) is doped.

The luminous layer 15 is formed under a condition that the in-furnace pressure is, for example, 100 kPa and the in-furnace temperature is, for example, 830 degrees Celsius.

### [Forming the Hole Supply Layer]

Yet subsequently, the in-furnace pressure and the in-furnace temperature are set to predetermined values, respectively. Then, trimethyl gallium, trimethyl aluminum, biscyclo pentadienyl magnesium and ammonia, all of which are as source gases, are supplied into the treatment furnace while (with) flowing a nitrogen gas and a hydrogen gas, both of which are as carrier gases, so that a first P-type AlGaN layer is formed. Furthermore, with supplying another source gas in which a flow rate of trimethyl aluminum is changed out of the source gases, a second P-type AlGaN layer is formed that has different composition from the first P-type AlGaN layer. As a result, the hole supply layer 16 is formed that is composed of the first P-type AlGaN layer and the second P-type AlGaN layer. After then, a source gas other than trimethyl aluminum is supplied on the hole supply layer 16 so that on the hole supply layer 16, a contact layer 17 is formed that is composed of the N-type GaN by the vapor phase epitaxial growth method.

### [Forming the P- Electrode Layer, the P- Pad Electrode and the N- Pad Electrode]

By performing the preparation mentioned above, the nitride semiconductor is formed in which the electron supply layer, the protective layer, the luminous layer and the contact layer are formed on the substrate via (through) the low temperature buffer layer and the base layer. With respect to the formed nitride semiconductor, an activation treatment is applied to the nitride semiconductor in the nitride atmosphere, for example, at 500 degrees Celsius for 15 minutes.

Subsequently, by use of the photolithography and an inductively coupled type plasma equipment (i.e., ICP equipment), the photo etching treatment is applied to the hole supply layer 16 and the luminous layer 15 to remove (etch) a portion of the hope supply layer 16 and the luminous layer 15, so that the surface of the electron supply layer 13 is exposed.

Then, on the contact layer 17, a P- electrode layer 18 is formed that is composed of an Ni layer and an Au layer. Subsequently, in the atmosphere, the annealing treatment is applied to the formed nitride semiconductor at, for example, 500 degrees Celsius for 5 minutes. Then, Cr and Al are vapor-deposited on the surfaces of the P- electron layer 18 and the electron supply layer 13 so that a P- pad electrode 19a and an N- pad electrode 19b are formed, respectively. Accordingly, the nitride semiconductor device as shown in FIG. 1 is obtained.

According to the above mentioned nitride semiconductor device, the electron supply layer 13 has a composition of AlₓGa₁₋ₓN (where 0.01<x≦1). Therefore, even if the N-type impurity is doped at high concentration, still the electron supply layer 13 with flat (even) surface can be obtained. In addition, since a concentration of N-type impurity of the electron supply layer 13 is equal to or greater than 1×10¹⁹/cm³, then it can be achieved to lower the resistance of the electron supply layer 13. Accordingly, the nitride semiconductor device that operates at lower voltage and that has higher luminous efficiency can be obtained.

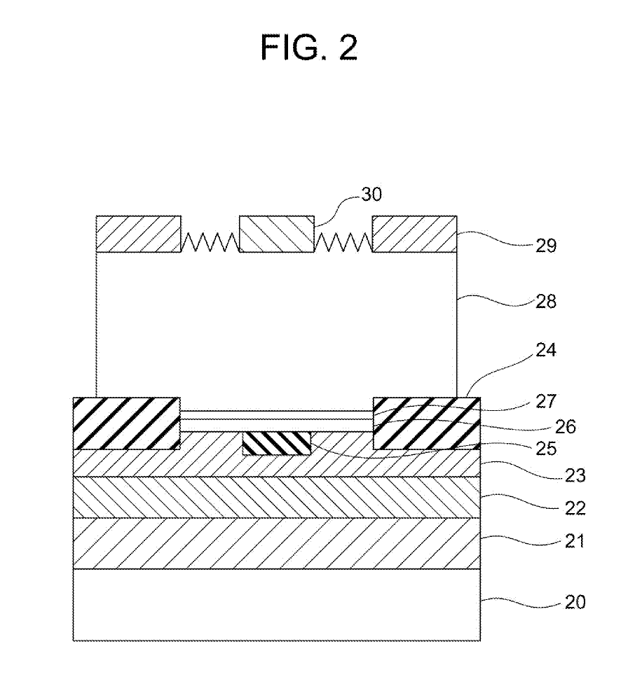

FIG. 2 is a cross-sectional view showing another exemplary nitride semiconductor device according to another embodiment of the present invention. This type of nitride semiconductor device is a vertical type structure constituted as a LED and has a substrate 20 which is composed of, for example, silicon (Si). On the substrate 20, a P- reflective electrode layer 23 that is composed of Ni/Au is formed via (through) a solder layer 21 in which a ratio of Au to Sn is, for example, 8:2 and a solder diffusion (dispersion) prevention layer 22 which is composed of Ti/Pt. On the P- reflective electrode layer 23, SiO₂ layers 24, 25 are formed in the circumferential region and the center region of the P- reflective electrode layer 23. On the P- reflective electrode layer 23 including the SiO₂ layer 25, a hole supply layer 26 which is composed of P-type nitride semiconductor is formed. Insulating film which is composed of SiN or the like may be formed in place of the SiO₂ layers 24, 25. Likewise, a layer which is composed of a conductive substance may be formed that performs a Schottky junction (contact) with the P-type nitride semiconductor layer in place of the SiO₂ layer 25. On the hole supply layer 26, the luminous layer 27 is formed. On the luminous layer 27, the electron supply layer 28 which is composed of the N-type nitride semiconductor is formed. On the electron supply layer 28, N- electrodes 29, 30 are formed.

In the above mentioned configuration or structure, the hole supply layer 26, the luminous layer 27 and the electron supply layer 28 have the similar configuration to the hole supply layer 16, the luminous layer 15 and the electron supply layer 13 of the nitride semiconductor device shown in FIG. 1, respectively.

As such, the hole supply layer 26, the luminous layer 27 and the electron supply layer 28 may be formed by a similar process or preparation to those of the hole supply layer 16, the luminous layer 15 and the electron supply layer 13 of the nitride semiconductor device shown in FIG. 1.

According to the above mentioned nitride semiconductor device, the electron supply layer 28 has a composition of AlₓGa₁₋ₓN (where 0.01<x≦1). Therefore, even if the N-type impurity is doped at high concentration, still the electron supply layer 28 with flat (even) surface can be obtained. In addition, as a concentration of N-type impurity of the electron supply layer 28 is equal to or greater than 1×10¹⁹/cm³, it can be achieved to lower the resistance of the electron supply layer 28. As a result, the nitride semiconductor device that operates at lower operating voltage and that has higher luminous efficiency can be obtained.

### EXAMPLES

Hereinafter, specific examples of the nitride semiconductor device according to the present embodiments will be explained. However, it should be noted that the present invention is not limited to these particular examples.

### Experimental Example 1

### (1) Forming the Low Temperature Buffer Layer

A C plane sapphire substrate was disposed within the treatment furnace of the CVD equipment. Then, while flowing a hydrogen gas at a flow rate of 10 slm (standard liter per minute) into the treatment furnace, the in-furnace temperature was elevated up to, for example, 1,150 degrees Celsius so as to clean the c plane sapphire substrate.

Subsequently, in the CVD equipment, the in-furnace pressure was set to 100 kPa, and the in-furnace temperature was set to 480 degrees Celsius. Then, with flowing a nitrogen gas and a hydrogen gas, both of which were as carrier gases, at a flow rate of 5 slm, respectively, into the treatment furnace, trimethyl gallium at a flow rate of 50 μmol/min and ammonia at a flow rate of 250,000 μmol/min, both of which were as source gases, were supplied into the treatment furnace for 68 seconds. As a result, the low temperature buffer layer which was composed of GaN with the thickness of 20 nm was formed on the surface of the C (chamfer) plane sapphire substrate.

### (2) Forming the Base Layer

Subsequently, the in-furnace temperature in the CVD equipment was elevated up to 1,150 degrees Celsius. Then, with flowing a nitrogen gas at a flow rate of 20 slm and a hydrogen gas at a flow rate of 15 slm, both of which were as carrier gases, into the treatment furnace, trimethyl gallium at a flow rate of 100 μmol/min and ammonia at a flow rate of 250,000 μmol/min, both of which were as source gases, were supplied into the treatment furnace for 30 minutes. As a result, the base layer which was composed of GaN with the thickness of 1.7 μm was formed on the surface of the first buffer layer.

### (3) Forming the Electron Supply Layer

Yet subsequently, the in-furnace pressure in the CVD equipment was set to 30 kPa. Then, with flowing a nitrogen gas at a flow rate of 20 slm and a hydrogen gas at a flow rate of 15 slm, both of which were as carrier gases, into the treatment furnace, tri methylgallium at a flow rate of 94 μmol/min, trimethyl aluminum (TMAl) at a flow rate of 6 μmol/min, ammonia at a flow rate of 250,000 μmol/min and tetraethyl silane at a flow rate of 0.13 μmol/min, all of which were as source gases, were supplied into the treatment furnace for 30 minutes. As a result, the electron supply layer with the thickness of 1.7 μm was formed on the surface of the base layer.

### (4) Analysis of the Obtained Electron Supply Layer

When the obtained electron supply layer was analyzed, it was observed that the obtained electron supply layer had a composition of Al_{0.06}Ga_{0.94}N and Si concentration of 5×10¹⁹/cm³.

Further, when the surface of the obtained electron supply layer was observed, it was confirmed that the electron supply layer had a mirror (specular) surface.

### Comparative Experimental Example 1

By carrying out the similar preparation to the above mentioned (1) and (2) of the Example 1, on the surface of the C plane sapphire substrate, the low temperature buffer layer which was composed of GaN with the thickness of 20 nm and the base layer which was composed of GaN with the thickness of 1.7 μm were formed.

Subsequently, the in-furnace pressure in the CVD equipment was set to 30 kPa. Then, with flowing a nitrogen gas at a flow rate of 20 slm and a hydrogen gas at a flow rate of 15 slm, both of which were as carrier gases, into the treatment furnace, trimethyl gallium at a flow rate of 100 μmol/min, ammonia at a flow rate of 250,000 μmol/min and tetraethyl silane at a flow rate of 0.05 μmol/min, all of which were as source gases, were supplied into the treatment furnace for 53 minutes. As a result, the electron supply layer with the thickness of 3 μm was formed on the surface of the base layer.

When the obtained electron supply layer was analyzed, it was observed that the electron supply layer had a composition of GaN and Si concentration of 2×10¹⁹/cm³.

Further, when the surface of the electron supply layer was observed, it was confirmed that the electron supply layer had a roughened surface (surface roughness).

### Working Example 1

### (1) Forming the Low Temperature Buffer Layer and the Base Layer

By carrying out the similar preparation to the above mentioned (1) and (2) of the Example 1, on the surface of the C plane sapphire substrate, the low temperature buffer layer which was composed of GaN with the thickness of 20 nm and the base layer composed of GaN with the thickness of 1.7 μm were formed.

### (2) Forming the Electron Supply Layer and the Protective Layer

Subsequently, the in-furnace pressure in the CVD equipment was set to 30 kPa. Then, with flowing a nitrogen gas at a flow rate of 20 slm and a hydrogen gas at a flow rate of 15 slm, both of which were as carrier gases, into the treatment furnace, trimethyl gallium at a flow rate of 94 μmol/min, trimethyl aluminum (TMAl) at a flow rate of 6 μmol/min, ammonia at a flow rate of 250,000 μmol/min and tetraethyl silane at a flow rate of 0.025 μmol/min, all of which were as source gases, were supplied into the treatment furnace for 30 minutes. As a result, the electron supply layer with the thickness of 1.7 μm that had a composition of Al_{0.06}Ga_{0.94}N and Si concentration of 1×10¹⁹/cm³ was formed on the surface of the base layer. After then, while stopping the supply of trimethyl aluminum, other source gases were still supplied for 6 seconds. As a result, the protective layer which was composed of N-type GaN with the thickness of 5 nm was formed.

### (3) Forming the Luminous Layer

Yet subsequently, the in-furnace pressure in the CVD equipment was set to 100 kPa, and the in-furnace temperature was set to 830 degrees Celsius. Then, with flowing a nitrogen gas at a flow rate of 15 slm and a hydrogen gas at a flow rate of 1 slm, both of which were as carrier gases, into the treatment furnace, trimethyl gallium at a flow rate of 10 μmol/min, trimethyl indium at a flow rate of 12 μmol/min and ammonia at a flow rate of 300,000 μmol/min, all of which were as source gases, were supplied into the treatment furnace for 48 seconds. After then, trimethyl gallium at a flow rate of 10 μmol/min, trimethyl aluminum at a flow rate of 1.6 μmol/min, tetraethyl silane at a flow rate of 0.002 μmol/min and ammonia at a flow rate of 300,000 μmol/min were supplied into the treatment furnace for 120 seconds. The above mentioned gas supply operations were repeated. As a result, on the surface of the electron supply layer, the luminous layer was formed that has a multiple quantum well structure that was formed by periodically laminating (stacking) the well layer which was composed of GaInN with the thickness of 2 nm and the barrier layer which was composed of N-type AlGaN with the thickness of 7 nm by 15 times (cycles), respectively.

### (4) Forming the Hole Supply Layer and the Contact Layer

Subsequently, while keeping the in-furnace pressure in the CVD equipment at 100 kPa, the in-furnace temperature was elevated up to 1,050 degrees Celsius with flowing a nitrogen gas at a flow rate of 15 slm and a hydrogen gas at a flow rate of 25 slm, both of which were as carrier gases. After then, trimethyl gallium at a flow rate of 35 μmol/min, trimethyl aluminum 20 μmol/min, ammonia at a flow rate of 250,000 μmol/min and biscyclo pentadienyl at a flow rate of 0.1 μmol/min, all of which were as source gases, were supplied into the treatment furnace for 60 seconds. As a result, on the surface of the luminous layer, P-type semiconductor layer was formed that has a composition of Al_{0.3}Ga_{0.7}N with the thickness of 20 nm. After then, a source gas in which the flow rate of trimethyl aluminum was changed to 9 μmol/min was supplied for 360 seconds. As a result, the P-type semiconductor layer was formed that has a composition of Al_{0.13}Ga_{0.87}N with the thickness of 120 nm. Yet after then, while stopping the supply of trimethyl aluminum, source gases in which the flow rate of biscyclo pentadienyl was changed to 0.2 μmol/min were supplied for 20 seconds. As a result, the contact layer which was composed of P-type GaN with the thickness of 5 nm was formed.

### (5) Forming the P- Electrode Layer, P- Pad Electrode and N-Pad Electrode

By carrying out (performing) the above mentioned preparations, the nitride semiconductor was prepared in which the electron supply layer, the protective layer, the luminous layer, the hole supply layer and the contact layer were formed on the C plane sapphire substrate, via (through) the low temperature buffer layer and the base layer. In the nitride atmosphere, the activation treatment was applied to the prepared nitride semiconductor at, for example, 500 degrees Celsius for 15 minutes.

Subsequently, by use of the photolithography and the ICP equipment (i.e., Inductive Coupling type Plasma equipment), the photo etching treatment was applied to the hole supply layer 16 and the luminous layer 15 of the nitride semiconductor to remove (etch) a portion (part) of the hole supply layer 16 and the luminous layer 15. Thus, the surface of the electron supply layer was exposed. Then, on the contact layer, the P- electrode layer was formed that was composed of a Ni layer with the thickness of 3 nm and an Au layer with the thickness of 3 nm. After then, an annealing treatment was applied to the nitride semiconductor in the atmosphere at 500 degrees Celsius for 5 minutes. Subsequently, Cr and Al were vapor deposited on the surfaces of the P- electrode layer and the electron supply layer. As a result, the P- pad electrode and N- pad electrode, each of which was composed of a Cr layer of 30 nm and an Au layer of 200 nm, were formed. Accordingly, the lateral type structured nitride semiconductor device as shown in FIG. 1 was fabricated. The luminous (light-emitting) peak wavelength of this nitride semiconductor device is 365 nm.

### Working Example 2

The lateral type structured nitride semiconductor device shown in FIG. 1 was fabricated by the similar preparation (process) to the Example 1 except that the electron supply layer and the protective layer were formed as follows. The luminous (light emitting) peak wavelength of this type of nitride semiconductor device is 365 nm.

The in-furnace pressure in the CVD equipment was set to 30 kPa. Then, with flowing into the treatment furnace a nitrogen gas at a flow rate of 20 slm and a hydrogen gas at a flow rate of 15 slm, both of which were as carrier gases, trimethyl gallium at a flow rate of 94 μmol/min, tri methyl aluminum 6 μmol/min, ammonia at a flow rate of 250,000 μmol/min and tetraethyl silane at a flow rate of 0.13 μmol/min, all of which were as source gases, were supplied into the treatment furnace for 30 minutes. As a result, an electron supply layer with the thickness of 1.7 μm that had a composition of Al_{0.06}Ga_{0.94}N and Si concentration of 5×10¹⁹/cm³ was formed on the surface of the base layer. After then, stopping the supply of trimethyl aluminum, while keeping to provide source gases other than trimethyl aluminum for 6 seconds. As a result, a protective layer that was composed of N-type GaN with the thickness of 5 nm was formed.

### Comparative Example 1

In place of the electron supply layer and the protective layer that had compositions of Al_{0.06}Ga_{0.94}N being formed, by the similar preparation (process) to the Comparative Experimental Example 1, the lateral type structured nitride semiconductor device was fabricated by the similar preparation (process) to the Working Example 1 except that trimethyl aluminum (TMAl) was not supplied under the condition for forming Al_{0.06}Ga_{0.94}N and that the electron supply layer which was composed of GaN having Si concentration of 1×10¹⁹/cm³ was formed.

Each of the nitride semiconductor devices obtained in the Working Examples 1 and 2 and Comparative Example 1 was mounted onto the TO-18 stem package to fabricate the LED device. A current of 20 mA was applied to the obtained LED device to allow the LED device to emit light. In this state, the operating voltages of the LED devices were measured, and light (optical) outputs were measured by a photo detector at a position distant from the LED devices by 5 mm. The measurement results are shown in the following Table 1.

TABLE 1

| | | Operating | Power |
|---|---|---|---|
| | Output (mW) | Voltage (V) | Efficiency (%) |
| Working Example 1 | 2.8 | 3.7 | 3.8 |
| Working Example 2 | 3.0 | 3.5 | 4.3 |
| Comparative Example 1 | 2.6 | 3.6 | 3.6 |

As shown in the measurement results shown in Table 1, according to the nitride semiconductor device of the Working Examples 1 and 2, it is confirmed that the nitride semiconductor device can be obtained that operates at a lower operating voltage and that has higher luminous efficiency. On the contrary, according to the nitride semiconductor device of the Comparative Example 1, the light output is lower and the luminous efficiency is also lower.

### Working Example 3

### (1) Forming the Low Temperature Buffer Layer

A C plane sapphire substrate was disposed in the treatment furnace of the CVD equipment. Then, in-furnace temperature was elevated up to, for example, 1,300 degrees Celsius with flowing a hydrogen gas at a flow rate of 10 slm into the treatment furnace so as to clean the C plane sapphire substrate.

Subsequently, an in-furnace pressure was set to 10 kPa. Then, with flowing a nitrogen gas and a hydrogen gas, both of which were carrier gases, at a flow rate of 8 slm, respectively, into the treatment furnace, an in-furnace temperature was set to 950 degrees Celsius, and trimethyl aluminum at a flow rate of 8.7 μmol/min and ammonia at a flow rate of 13,920 μmol/min, both of which were source gases, were supplied into the treatment furnace for 700 seconds. As a result, the low temperature buffer layer which was composed of AlN (aluminum nitride) with the thickness of 50 nm was formed on the surface of the C plane sapphire substrate.

### (2) Forming the Base Layer

Subsequently, in-furnace temperature was elevated up to 1,350 degrees Celsius in the treatment furnace of the CVD equipment. Then, with flowing a nitrogen gas and a hydrogen gas, both of which were carrier gases, at a flow rate of 8 slm, respectively, into the treatment furnace, trimethyl aluminum 50 μmol/min and ammonia at a flow rate of 22,000 μmol/min, both of which were source gases, were supplied into the treatment furnace for 80 minutes. As a result, the base layer which was composed of AlN with the thickness of 1 μm was formed on the surface of the low temperature buffer layer.

### (3) Forming the Electron Supply Layer and the Protective Layer

Subsequently, the in-furnace pressure in the CVD equipment was set to 30 kPa and the in-furnace temperature was set to 1,170 degrees Celsius. Then, with flowing a nitrogen gas at a flow rate of 15 slm and a hydrogen gas at a flow rate of 12 slm, both of which were as carrier gases, into the treatment furnace, trimethyl gallium at a flow rate of 80 μmol/min, trimethyl aluminum at a flow rate of 20 μmol/min, ammonia at a flow rate of 250,000 μmol/min and tetraethyl silane at a flow rate of 0.07 μmol/min, all of which were as source gases, were supplied into the treatment furnace for 17 minutes. As a result, the electron supply layer with the thickness of 1 μm that had a composition of Al_{0.2}Ga_{0.8}N and Si concentration of 3×10¹⁹/cm³ was formed on the surface of the base layer. After then, while stopping the supply of trimethyl aluminum, other source gases were still supplied for 7 seconds. As a result, the protective layer which was composed of N-type GaN with the thickness of 5 nm was formed.

### (4) Forming the Luminous Layer

Yet subsequently, the in-furnace pressure in the CVD equipment was set to 60 kPa. Then, with flowing a nitrogen gas at a flow rate of 16 slm as a carrier gas into the treatment furnace, the in-furnace temperature was set to 840 degrees Celsius. After then, trimethyl gallium at a flow rate of 10 μmol/min, trimethyl aluminum at a flow rate of 2 μmol/min, tri methyl indium at a flow rate of 35 μmol/min and ammonia at a flow rate of 300,000 μmol/min, all of which were as source gases, were supplied into the treatment furnace for 48 seconds. Yet after then, trimethyl gallium at a flow rate of 10 μmol/min, trimethyl aluminum at a flow rate of 4 μmol/min, tetraethyl silane at a flow rate of 0.002 μmol/min and ammonia at a flow rate of 300,000 μmol/min were supplied into the treatment furnace for 120 seconds. The above mentioned source gas supply operations were repeated. As a result, on the surface of the electron supply layer, the luminous layer was formed that had a multiple quantum well structure that was formed by periodically laminating (stacking) the well layer which was composed of GaInN with the thickness of 2 nm and the barrier layer which was composed of N-type AlGaN with the thickness of 7 nm by 15 times (cycles), respectively.

### (5) Forming the Hole Supply Layer and the Contact Layer

Subsequently, while keeping the in-furnace pressure of the CVD equipment at 60 kPa, the in-furnace temperature was elevated up to 1,050 degrees Celsius with flowing a nitrogen gas at a flow rate of 15 slm and a hydrogen gas at a flow rate of 25 slm, both of which were as carrier gases. After then, trimethyl gallium at a flow rate of 100 μmol/min, trimethyl aluminum at a flow rate of 40 μmol/min, ammonia at a flow rate of 250,000 μmol/min and biscyclo pentadienyl at a flow rate of 0.26 μmol/min, all of which were as source gases, were supplied into the treatment furnace for 20 seconds. As a result, on the surface of the luminous layer, a P-type semiconductor layer was formed that has a composition of Al_{0.35}Ga_{0.65}N with the thickness of 20 nm. After then, a source gas in which the flow rate of tri methyl aluminum was changed to 25 μmol/min was supplied for 100 seconds. As a result, the P-type semiconductor layer was formed that has a composition of Al_{0.2}Ga_{0.8}N with the thickness of 100 nm. Yet after then, while stopping the supply of trimethyl aluminum, source gases in which the flow rate of biscyclo pentadienyl was changed to 0.2 μmol/min were supplied for 5 seconds. As a result, the contact layer which was composed of P-type GaN with the thickness of 5 nm was formed.

### (5) Forming the P- Electrode Layer, P- Pad Electrode and N-Pad Eelectrode

By carrying out (performing) the above mentioned preparations, the nitride semiconductor was prepared in which the electron supply layer, the protective layer, the luminous layer, the hole supply layer and the contact layer were formed on the substrate, via (through) the low temperature buffer layer and the base layer. In the nitride atmosphere, the activation treatment was applied to the prepared nitride semiconductor at 500 degrees Celsius for 15 minutes.

Subsequently, by use of the photolithography and the ICP equipment (i.e., Inductive Coupling type Plasma equipment), the photo etching treatment was applied to the hole supply layer 16 and the luminous layer 15 of the nitride semiconductor to remove (etch) a portion (part) of the hole supply layer 16 and the luminous layer 15. Thus, the surface of the electron supply layer was exposed. Then, on the contact layer, the P- electrode layer was formed which was composed of a Ni layer with the thickness of 3 nm and an Au layer with the thickness of 3 nm. After then, an annealing process (treatment) was applied to the nitride semiconductor in the atmosphere at 500 degrees Celsius for 5 minutes. Subsequently, Cr and Al were vapor deposited on the surfaces of the P- electrode layer and the electron supply layer. As a result, the P- pad electrode and N- pad electrode, each of which was composed of a Cr layer of 30 nm and an Au layer of 200 nm, were formed. Accordingly, the lateral type structured nitride semiconductor device as shown in FIG. 1 was fabricated. The luminous (light-emitting) peak wavelength of the nitride semiconductor device is 340 nm.

Each of the nitride semiconductor devices obtained in the Working Example 3 was mounted onto the TO-18 stem package to fabricate the LED device. A current of 20 mA was applied to the obtained LED device to allow the LED device to emit light. In this state, the operating voltages of the LED devices were measured, and light (optical) outputs were measured by a photo detector at a position distant from the LED devices by 5 mm. As a result, it was observed that the light (optical) output was 0.5 mW, the operating voltage was 4.2 V and the power efficiency was 0.6%.

### Working Example 4

The nitride semiconductor device was fabricated by the similar process to the Working Example 2 that the electron supply layer, the protective layer, the luminous layer, the hole supply layer and the contact layer were formed on the C plane sapphire substrate via (through) the low temperature layer and the base layer. In the nitride atmosphere, the activation treatment was applied to the prepared nitride semiconductor at 500 degrees Celsius for 15 minutes.

Subsequently, by use of the photolithography and the ICP equipment (i.e., Inductive Coupling type Plasma equipment), the photo etching treatment was applied to the circumferential portion of the contact layer, the hole supply layer and the luminous layer of the nitride semiconductor. Thus, the surface of the circumferential portion of the electron supply layer was exposed. Then, by use of the sputter equipment, SiO₂ layer with the thickness of 400 nm was formed on the exposed surface of the circumferential portion of the electron supply layer and on the surface of the center portion of the contact layer. After then, by use of the sputter equipment, the P- reflective electrode layer which was composed of the Ni layer with the thickness of 0.7 nm and the Ag layer with the thickness of 120 nm was formed on the entire (overall) exposed surfaces of the contact layer and the SiO₂ layer, respectively.

By carrying out (performing) the above mentioned preparations, the nitride semiconductor was prepared in which the SiO₂ layer and P- reflective electrode layer were formed. In the dry air atmosphere, the contact annealing treatment was applied to the prepared nitride semiconductor at 400 degrees Celsius for 2 minutes by use of the rapid thermal annealing device (RTA).

Yet subsequently, a solder diffusion prevention layer that was formed by periodically laminating a Ti layer with the thickness of 100 nm and the Pt layer with the thickness of 200 nm by 3 times (cycles) on the P- reflective electrode by use of the electron beam deposition equipment (EB).

On the other hand, a solder layer with the thickness of 4 μm in which the proportion of Au to Sn is 8:2 was formed via (through) Ti film with the thickness of 10 nm by use of the electron beam deposition equipment (EB). Then, on the solder layer formed on the silicon substrate, the nitride semiconductor in which the above mentioned solder diffusion prevention layer was formed was aligned and disposed such that the solder diffusion prevention layer be contacting the solder layer. After then, the heating and pressurization treatment was applied to the nitride semiconductor so that both of the solder diffusion prevention layer and the solder layer were joined each other.

Yet subsequently, by irradiating a KrF excimer laser, the sapphire substrate was exfoliated from the low temperature buffer layer. Then, by use of the ICP equipment, the low temperature buffer layer and the base layer were removed from the nitride semiconductor so that the surface of the electron supply layer was exposed. After then, by use of a potassium hydroxide solution, the surface roughening treatment was applied to the surface of the electron supply layer. Yet after then, on the surface of the electron supply layer, the N-electrode which was composed of the Cr layer with the thickness of 100 nm and the Au layer with the thickness of 3 μm was formed.

Accordingly, in the nitride atmosphere, vertical type structured nitride semiconductor device was fabricated as shown in FIG. 2 by applying the sintering treatment at 250 degrees Celsius for 1 minute. The luminous (light emitting) peak wavelength of the fabricated nitride semiconductor device is 365 nm.

Each of the nitride semiconductor devices obtained in the Working Example 4 was mounted onto the package for the surface mounting to fabricate the LED device. A current of 350 mA was applied to the obtained LED device to allow the LED device to emit light. In this state, the operating voltages of the LED devices were measured, and light (optical) outputs were measured by a photo detector at a position distant from the LED devices by 5 mm. As a result, it was observed that the light (optical) output was 150 mW, the operating voltage was 4.5 V and the power efficiency was 11%.

### REFERENCE SIGNS LIST

10 Substrate
11 Low Temperature Buffer Layer
12 Base Layer
13 Electron Supply Layer
14 Protective Layer
15 Luminous Layer
16 Hole Supply Layer
17 Contact Layer
18 P- Electrode Layer
19a P- Pad Electrode
19b N- Pad Electrode
20 Substrate
21 Solder Layer
22 Solder Diffusion Prevention Layer
23 P- Reflective Electrode Layer
24, 25 SiO₂ Layers
26 Hole Supply Layer
27 Luminous Layer
28 Electron Supply Layer
29, 30 N- Electrodes

1-2. (canceled)

3. A nitride semiconductor device comprising:
an electron supply layer composed of an N-type semiconductor,
the electron supply layer having:
a composition of AlₓGa₁₋ₓN (where 0.01<x≦1);
a concentration of an N-type impurity equal to or greater than 3×10¹⁹/cm³; and
a thickness equal to or greater than 0.5 μm.

4. The nitride semiconductor device according to claim 1, wherein the N-type impurity is silicon (Si).
